(19) United States
(12) Patent Application Publication
(10) Pub. No.: US 2014/0326956 A1
(43) Pub. Date: Nov. 6, 2014

(54) ORGANIC LIGHT EMITTING DISPLAY DEVICE AND MANUFACTURING METHOD THEREOF

(71) Applicant: SAMSUNG DISPLAY CO., LTD., Yongin-si (KR)

(72) Inventors: Seong-Min WANG, Suwon-si (KR); Mu-Gyeom KIM, Yongin-si (KR); Gug Rae JO, Asan-si (KR); Dae Young LEE, Seoul (KR); Jung Gun NAM, Seoul (KR); Dae Hwan JANG, Gwangmyeong-si (KR)

(21) Appl. No.: 13/962,693

(22) Filed: Aug. 8, 2013

(30) Foreign Application Priority Data
May 3, 2013 (KR) 10-2013-0050311

(51) Int. Cl. H01L 51/52

(52) U.S. Cl. CPC H01L 51/5225
USPC 257/40; 438/46

(57) ABSTRACT

An organic light emitting display device and a manufacturing method of an organic light emitting display device. An organic light emitting display device includes a substrate; a first electrode on the substrate; an emitting layer on the first electrode; a second electrode on the emitting layer; and a first slit-shaped pattern on the second electrode and including a plurality of first protrusions spaced apart from each other.

### CROSS-REFERENCE TO RELATED APPLICATION

This application claims priority to and the benefit of Korean Patent Application No. 10-2013-0050311, filed on May 3, 2013 in the Korean Intellectual Property Office, the entire content of which is incorporated herein by reference.

### BACKGROUND

1. Field

Aspects of embodiments of the present invention relate to an organic light emitting display device and a manufacturing method thereof.

2. Description of the Related Art

An organic light emitting display device is a self-emission display device which has an organic light emitting diode that emits light to display an image. In general, a comparable organic light emitting display device has a structure in which a display unit 20 is formed on a substrate 10 as illustrated in FIG. 1. The display unit 20 includes a first electrode 21 and a second electrode 23 for injecting a hole and an electron, respectively, and an emitting layer 22 is disposed between the first electrode 21 and the second electrode 23. In the organic light emitting display device, a hole supplied from a hole injection electrode (the first electrode) and an electron supplied from an electron injection electrode (the second electrode) are coupled to each other in the emitting layer to form an exciton, and light is generated when the above formed exciton falls to a ground state.

The organic light emitting display device may be classified as a top emission type or a bottom emission type according to a direction in which the light generated from the emitting layer is displayed. The bottom emission type has a structure in which light is displayed by passing through a substrate, and the top emission type has a structure in which light is displayed on an opposite side of the substrate.

FIG. 1 illustrates an example of a top emission type organic light emitting display device in which light is displayed on an opposite side of a substrate. In the organic light emitting display device shown in FIG. 1, a protecting layer 24 is disposed on the second electrode 23 so as to protect the display unit 20 and a window 50 is disposed to be spaced apart from the protecting layer 24. A space 40 may be formed between the protecting layer 24 and the window 50.

In the comparable organic light emitting display device, a polarizer (POL) 41 is disposed on a display surface in order to prevent visibility deterioration by an incidence of light from the outside. The polarizer 41 polarizes the light incident from the outside, and thus prevents the light, which has been incident to the inside of the organic light emitting display device and reflects therein, from being emitted to the outside. As a result, reduction of a contrast ratio (CR) due to external light may be prevented. In the case where the polarizer 41 is used, a TAC film 42 for supporting the polarizer 41 and an adhesive such as an OCA 43 for bonding the polarizer 41 to the window 50 are used.

As such, when a polarizer 41 is used, a thickness of the organic light emitting display device may increase by using a TAC film and an adhesive.

### SUMMARY

According to an aspect of embodiments of the present invention, an organic light emitting display device has a slit-shaped pattern on an electrode, which serves as a polarizer. According to another aspect of embodiments of the present invention, an organic light emitting display device is capable of preventing or substantially preventing deterioration of visibility due to external light by forming a slit-shaped pattern on an electrode.

According to another aspect of embodiments of the present invention, an organic light emitting display device has decreased thickness because a polarizer is not used.

According to another aspect of embodiments of the present invention, a manufacturing method of an organic light emitting display device is provided in which a slit-shaped pattern is provided on an electrode.

According to one or more embodiments of the present invention, an organic light emitting display device includes: a substrate; a first electrode on the substrate; an emitting layer on the first electrode; a second electrode on the emitting layer; and a first slit-shaped pattern on the second electrode and including a plurality of first protrusions spaced apart from each other.

The second electrode may transmit light. In one embodiment, the second electrode may be a transparent electrode.

The organic light emitting display device may include a second slit-shaped pattern on the first electrode and including a plurality of second protrusions spaced apart from each other.

The second slit-shaped pattern on the first electrode may have a same structure as the first slit-shaped pattern on the second electrode.

A cross section of a protrusion of the plurality of first protrusions may have a quadrangular shape or a U-shape.

A protrusion of the plurality of first protrusions may have a height of about 100 nm to about 200 nm and a width of about 30 nm to about 100 nm.

A distance, or pitch, between adjacent protrusions of the plurality of first protrusions may be about 60 nm to about 250 nm.

The first protrusions may include at least one of a metal or a metal oxide.

The metal may include at least one selected from the group consisting of aluminum (Al), chromium (Cr), and silver (Ag).

The first protrusions may include a metal layer.

A black matrix layer may be disposed on the metal layer. For example, the black matrix layer may be laminated on the metal layer.

The black matrix layer may cover a surface of the metal layer.

The black matrix layer may be formed by metal oxide.

The metal oxide may include at least one selected from the group consisting of aluminum oxide, chromium oxide, and silver oxide.

According to another embodiment of the present invention, a manufacturing method of an organic light emitting display device includes: forming a first electrode on a substrate; forming an emitting layer on the first electrode; forming a second electrode on the emitting layer; and forming a first slit-shaped pattern on the second electrode, the first slit-shaped pattern including a plurality of first protrusions spaced apart from each other.

In the forming of the first slit-shaped pattern, at least one of a metal or a metal oxide may be used to form the first protrusions.

The forming of the first slit-shaped pattern may include: preparing a transfer sheet having the plurality of first protrusions thereon; and transferring the plurality of first protrusions from the transfer sheet to the second electrode.

The method may include forming a second slit-shaped pattern on the first electrode after the forming the first electrode and before the forming the emitting layer, the second slit-shaped pattern including a plurality of second protrusions spaced apart from each other.

The forming the second slit-shaped pattern on the first electrode may be performed in a same manner as the forming the first slit-shaped pattern on the second electrode.

According to an aspect of embodiments of the present invention, an organic light emitting display device includes a slit-shaped pattern on an electrode and the slit-shaped pattern serves as a polarizer. As a result, a polarizer and a TAC film are not required, and thus a total thickness of the organic light emitting display device may be decreased.

According to an aspect of embodiments of the present invention, the organic light emitting display device may be manufactured without using a polarizer, which increases slimness of the device. Further, since the polarizer is not used and a thickness may be reduced, flexibility may increase, and durability for bending may be improved. As a result, a flexible organic light emitting display device may be manufactured.

The foregoing summary is illustrative only and is not intended to limit the present invention. In addition to the illustrative aspects, embodiments, and features described above, further aspects, embodiments, and features will become apparent by reference to the drawings and the following description of some embodiments of the present invention.

### BRIEF DESCRIPTION OF THE DRAWINGS

The above and other features and aspects of the present invention will become more apparent by describing in further detail some exemplary embodiments thereof with reference to the attached drawings.

FIG. 1 is a schematic diagram of a comparative example of an organic light emitting display device.

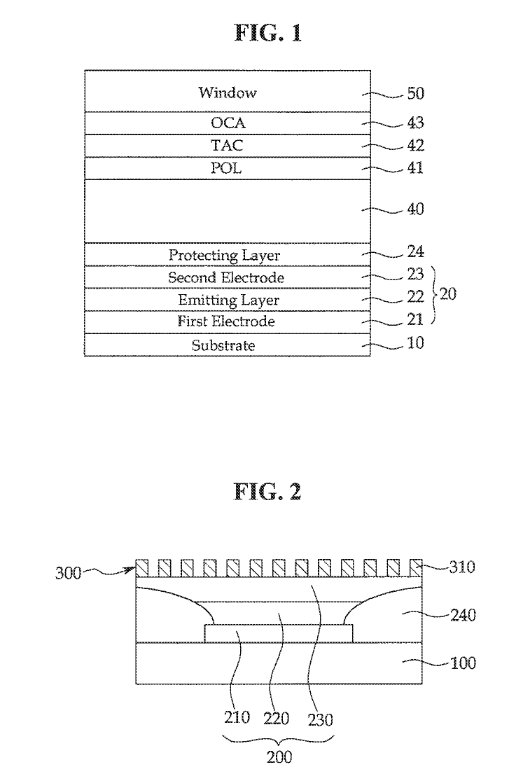

FIG. 2 is a schematic diagram illustrating an organic light emitting display device according to an embodiment of the present invention.

FIG. 3 is a schematic perspective view illustrating a structure of a slit-shaped pattern formed on a second electrode in the organic light emitting display device of FIG. 2.

FIGS. 4A to 4C illustrate examples of a structure of a slit-shaped pattern formed on a second electrode in an organic light emitting display device according to various embodiments of the present invention.

FIG. 5 is a schematic diagram illustrating an organic light emitting display device according to another embodiment of the present invention.

FIG. 6 is a diagram illustrating a structure of an organic light emitting display device according to another embodiment of the present invention.

FIGS. 7A to 7H are schematic diagrams for describing a process of manufacturing an organic light emitting display device, according to an embodiment of the present invention.

FIG. 8 is a perspective view schematically illustrating a structure of a transfer sheet to form a slit-shaped pattern on an electrode, according to an embodiment of the present invention.

FIGS. 9A and 9B are diagrams illustrating examples of a form of a protrusion on a base sheet of a transfer sheet.

FIGS. 10A to 10C are diagrams for describing a process of forming a transfer sheet to form a slit-shaped pattern on an electrode, according to an embodiment of the present invention.

FIGS. 11A to 11E are diagrams for describing a process of forming a transfer sheet to form a slit-shaped pattern on an electrode, according to another embodiment of the present invention.

### DETAILED DESCRIPTION

In the following detailed description, some embodiments of the present invention are shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive.

Respective components and shapes thereof may be schematically drawn or exaggerated in the accompanying drawings for ease of understanding, and some components may be omitted. Therefore, the drawings should be regarded in order to help understanding of the present disclosure, and not as limiting the present invention. Like reference numerals designate like components in the drawings.

It should be understood that when a layer or an element is described as being “on” another layer or element, it may be directly disposed on another layer or element, or an intervening layer or element may also be present.

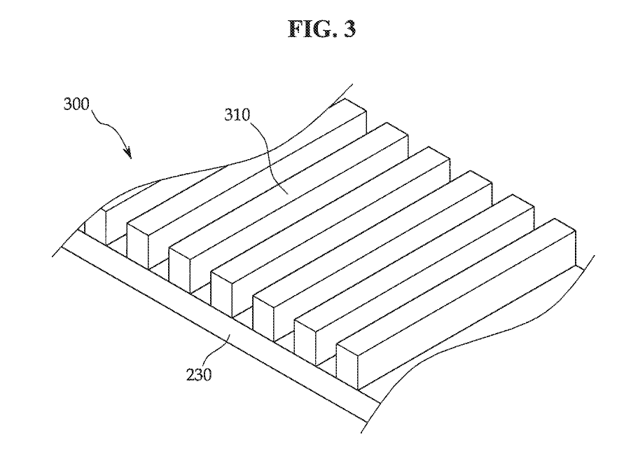

FIG. 2 schematically illustrates an example of an organic light emitting display device according to an embodiment of the present invention. In the organic light emitting display device illustrated in FIG. 2, a slit-shaped pattern 300 is formed on a display unit 200. The display unit 200 may include a first electrode 210 on a substrate 100, an emitting layer 220 on the first electrode 210, a second electrode 230 on the emitting layer 220, and the slit-shaped pattern 300 on the second electrode 230. In one embodiment, the slit-shaped pattern 300 on the second electrode 230 includes a plurality of protrusions 310 which are spaced apart from each other.

FIG. 2 illustrates a top emission type organic light emitting display device in which light generated from the emitting layer 220 is displayed on an opposite side of the substrate 100. According to an embodiment of the present invention, the slit-shaped pattern 300 is disposed on the second electrode 230 which is on a display direction side of the organic light emitting display device.

Hereinafter, embodiments of the present invention will be described based on a top emission type organic light emitting display device. However, the present invention is not limited thereto, and may also be applied to a bottom emission type organic light emitting display device.

The organic light emitting display device according to an embodiment of the present invention includes the substrate 100, the first electrode 210 on the substrate 100, the emitting layer 220 on the first electrode 210, the second electrode 230 on the emitting layer 220, and the slit-shaped pattern 300 disposed on the second electrode 230 and including the plurality of protrusions 310 spaced apart from each other.

In the organic light emitting display device illustrated in FIG. 2, the first electrode 210 may have a light transmission property (e.g., transmits light) or a reflection property. For example, the first electrode 210 may be formed by using indium tin oxide (ITO), indium zinc oxide (IZO), zinc oxide (ZnO), or indium oxide (In₂O₃) to have a light transmission property. Further, the first electrode 210 may be formed to have a reflection property comprising a reflection layer made of silver (Ag), magnesium (Mg), aluminum (Al), platinum (Pt), palladium (Pd), gold (Au), nickel (Ni), neodymium (Nd), iridium (Ir), chromium (Cr), or a compound thereof and a layer made of ITO, IZO, ZnO, or In₂O₃ on the reflection layer.

The second electrode 230 may have a light transmission property. For example, the second electrode 230 may have a layer made of lithium (Li), calcium (Ca), lithium fluoride/calcium (LiF/Ca), lithium fluoride/aluminum (LiF/AI), Al, Mg, or a compound thereof and a layer made of a material for forming a transparent electrode such as ITO, IZO, ZnO, or In₂O₃ thereon so as to have a light transmission property. That is, the second electrode 230 may be formed as a transparent electrode.

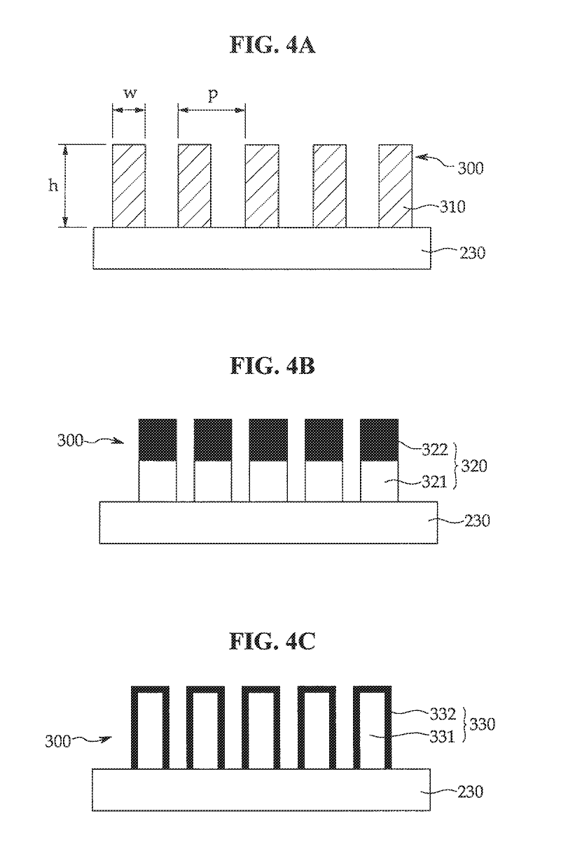

FIG. 3 schematically illustrates a structure of the slit-shaped pattern 300 formed on the second electrode 230, according to an embodiment of the present invention. As illustrated in FIG. 3, the slit-shaped pattern 300 has a plurality of protrusions 310 spaced apart from each other, and each of the plurality of protrusions 310 is formed in a long rod or strip shape and disposed to be spaced apart from an adjacent one of the protrusions 310, thereby forming a slit shape and, overall, the slit-shaped pattern 300.

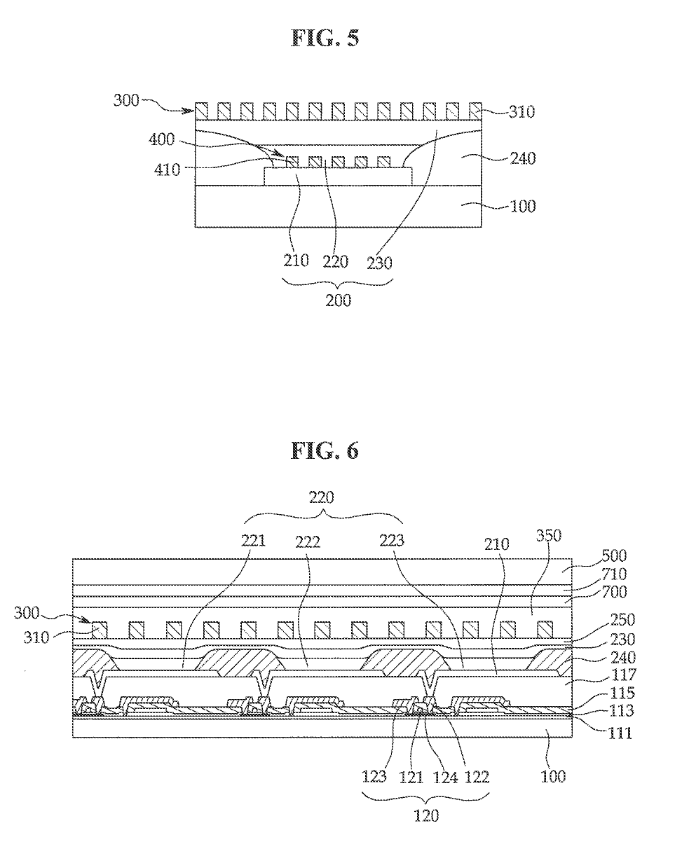

The slit-shaped pattern 300 may serve as a polarizer by controlling a size of a gap between the protrusions 310 by controlling a distance (pitch “p”) between the protrusions 310 and a width “w” of the protrusion 310 (gap=p−w) (see FIG. 4A).

The respective protrusions 310 configuring the slit-shaped pattern 300 may be formed in various shapes. That is, a cross-sectional shape of the protrusion 310 is not particularly limited. For example, a cross-section of the protrusion 310 may be quadrangular as illustrated in FIG. 3, or may have a U-shape or a downwardly facing U-shape (∩).

The slit-shaped pattern 300 may be formed by various materials. More specifically, the respective protrusions 310 configuring the slit-shaped pattern 300 may be formed by various materials, and may be formed by conductive materials or non-conductive materials. Further, the protrusion 310 may have a light reflection property or may not have a light reflection property.

The protrusion 310 may include at least one of a metal or a metal oxide. A metal applied to the metal and the metal oxide may include, for example, at least one of aluminum (Al), chromium (Cr), and silver (Ag).

In order to absorb light incident to the inside of the organic light emitting display device, and thus from the outside, and thus in order to prevent or substantially prevent external light from being reflected therein, a portion of the protrusion 310 to which the external light is incident may be formed of a material not having a light reflection property. For example, the portion of the protrusion 310 to which the external light is incident may be formed by using a light absorption material. As an example of the light absorption material, a metal oxide may be included.

FIGS. 4A to 4C illustrate some examples of a structure of the slit-shaped pattern 300 formed on the second electrode 230 in the organic light emitting display device, according to various embodiments of the present invention.

FIG. 4A illustrates an example in which the protrusion 310 is formed having a rectangular cross-sectional shape.

The protrusion 310 may include a metal layer. In one embodiment, the protrusion 310 may be formed of only a metal layer. Further, the protrusion 310 may be formed of a light absorption material. As the light absorption material for forming the protrusion 310, a metal oxide such as aluminum oxide (AlOx), chromium oxide (CrOx), or silver oxide (AgOx) may be used.

FIG. 4B illustrates a protrusion 320 according to another embodiment. Referring to FIG. 4B, the protrusion 320 may be formed having a structure in which a black matrix layer 322 is disposed on a metal layer 321. Since a metal generally has a light reflection property, the black matrix layer 322 is disposed on the metal layer 321 to absorb light incident from the outside. In this case, the black matrix layer 322 is disposed in a direction in which external light is incident. That is, the protrusion 320 of FIG. 4B is configured with two layers, which includes a metal layer 321 formed at a lower layer part, and a black matrix layer 322 disposed on the metal layer 321. In one embodiment, the black matrix layer 322 is laminated on the metal layer 321.

The protrusion 320 illustrated in FIG. 4B may be manufactured by forming the metal layer 321 on the second electrode 230, and then forming the black matrix layer 322 on the metal layer 321. In one embodiment, the black matrix layer 322 may be formed of a metal oxide.

FIG. 4C illustrates a protrusion 330 according to another embodiment of the present invention. The protrusion 330 illustrated in FIG. 4C has a structure in which a black matrix layer 332 covers a surface of a metal layer 331. That is, the black matrix layer 332 may cover, or surround, outer surfaces of the metal layer 331 on all sides.

The black matrix layers 322 and 332 may be formed of a metal oxide. As the metal oxide, for example, aluminum oxide, chromium oxide, or silver oxide may be used.

According to one embodiment of the present disclosure, the metal layer may be formed of aluminum (Al), and the black matrix layer may be formed of aluminum oxide. A metal material applied to form the metal layer, and a metal material applied to the metal oxide may be identical to each other or may not be identical to each other.

According to embodiments of the present invention, the slit-shaped pattern 300 may serve as a polarizer. Widths “w” and heights “h” of the protrusions 310, 320, and 330, and distances (pitch “p”) between the protrusions 310, 320, and 330 may be controlled so that the slit-shaped pattern 300 may serve as a polarizer.

The widths “w” and the heights “h” of the protrusions 310, 320, and 330, for example, may be determined within ranges of a width, a height, and a gap of slits in a conventional polarizer using linear polarization. The distance “p” between the protrusions 310, 320, and 330 is important for polarization, and the distance “p” may be varied depending on a wavelength of incident light. According to an embodiment of the present invention, when visible light passes through the slit-shaped pattern 300, the polarization is performed.

In general, if the distance “p” between the protrusions 310, 320, and 330 is too small, light does not pass. On the other hand, if the distance “p” between the protrusions is too large, the polarization is not performed well if the gap between the protrusions is larger than a wavelength of incident light. The distance between the protrusions 310, 320, and 330 may be selected so that the polarization may be performed, and, for reference, “gap=p−w”.

Accordingly, in an embodiment of the present invention, a distance (pitch “p” as shown in FIG. 4A) between the adjacent protrusions 310, 320, and 330 may be about 60 nm to about 250 nm.

In order to provide a sufficient path so that the incident light may be polarized, and in order to provide slimness of a display device and to prevent or substantially prevent the light from being lost when passing through the protrusions 310, 320, and 330, the heights “h” of the protrusions 310, 320, and 330, in one embodiment, are about 100 nm to about 200 nm.

When the widths “w” of the protrusions 310, 320, and 330 are too small, the protrusions do not function as a slit, and when the widths “w” of the protrusions 310, 320, and 330 are too large, light generated from the display unit is blocked too much. Accordingly, in an embodiment of the present invention, the widths “w” of the protrusions 310, 320, and 330 may be about 30 nm to about 100 nm.

As such, in the organic light emitting display device according to embodiments of the present invention, the slit-shaped pattern 300 including a plurality of protrusions may be used instead of a polarizer. As a result, an organic light emitting display device may be manufactured without using a polarizer, which improves slimness of the device. Further, since the polarizer is not used and thickness may be reduced, flexibility may increase, and durability of tensile and compressive stress for bending may be improved. As a result, a flexible organic light emitting display device may be manufactured.

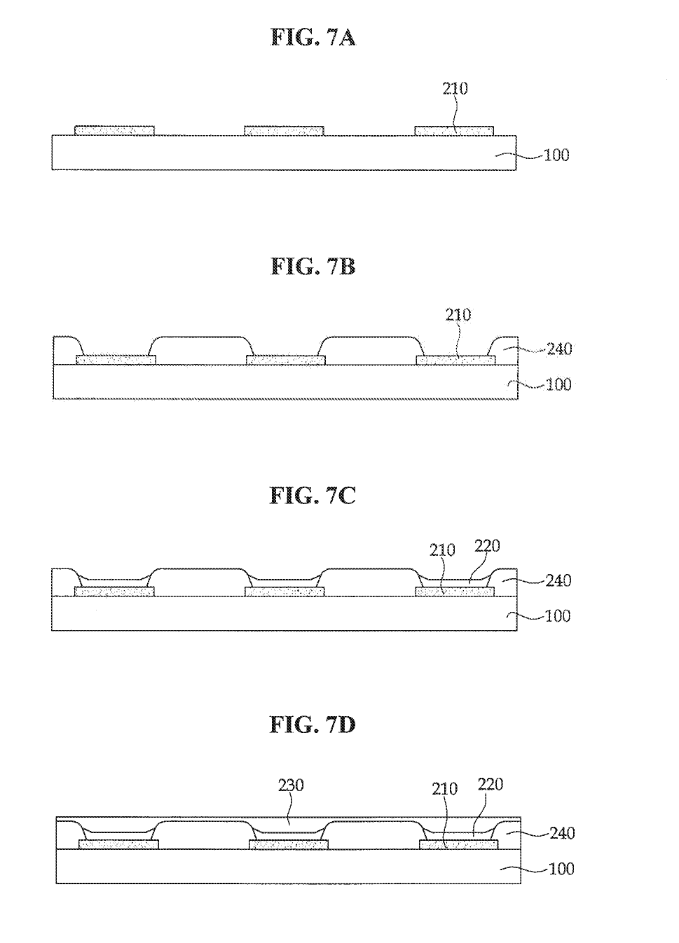

FIG. 5 illustrates an organic light emitting display device, according to another embodiment of the present invention, in which a slit-shaped pattern 400 which has a plurality of protrusions 410 spaced apart from each other, is disposed on the first electrode 210.

A structure of the slit-shaped pattern 400 on the first electrode 210, in one embodiment, may be the same as that of the slit-shaped pattern 300 on the second electrode 230. That is, a shape, a width, and a height of the protrusions 410 configuring the slit-shaped pattern 400 on the first electrode 210, and a distance between the protrusions 410 may be the same as a shape, a width, and a height of the protrusion 310 configuring the slit-shaped pattern 300 on the second electrode 230, and a distance between the protrusions 310.

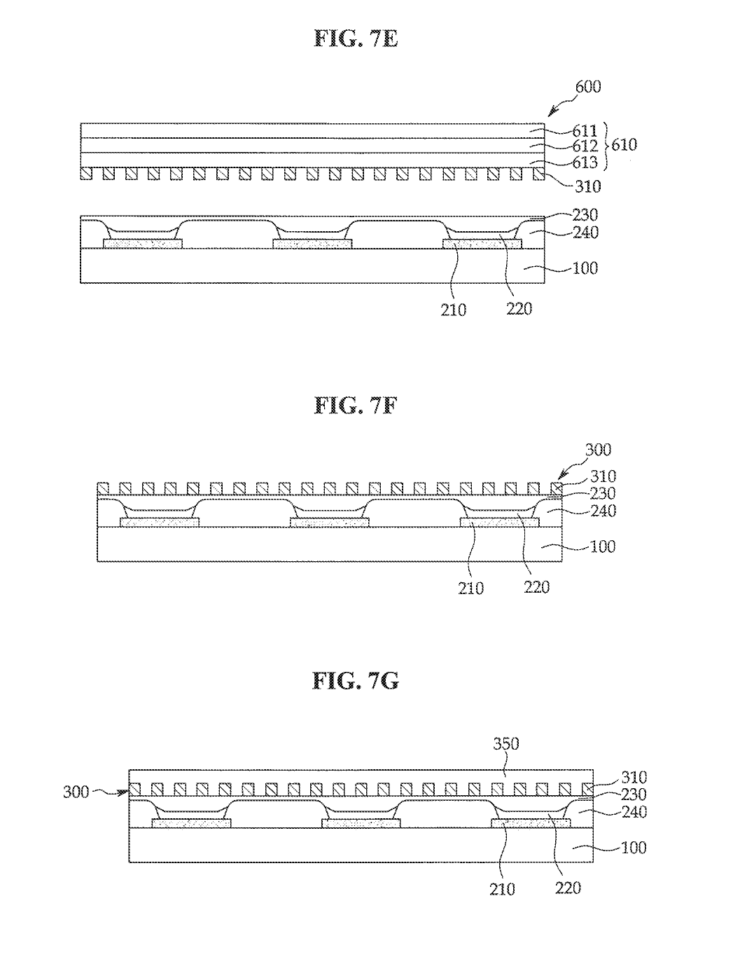

FIG. 6 illustrates an organic light emitting display device according to an embodiment of the present invention.

The organic light emitting display device illustrated in FIG. 6 includes the substrate 100, the first electrode 210 on the substrate 100, the emitting layer 220 on the first electrode 210, and the second electrode 230 on the emitting layer 220. The slit-shaped pattern 300 including the plurality of protrusions 310 is disposed on the second electrode 230.

The first electrode 210, the emitting layer 220, and the second electrode 230 form the display unit 200. A pixel defining layer (PDL) 240 is provided between the first electrodes 210 of the display unit 200. In the embodiment illustrated in FIG. 6, a top emission type organic light emitting display device in which light generated from the emitting layer 220 is displayed on an opposite side of the substrate 100 is exemplified.

Glass or polymer plastic which is generally used in the organic light emitting display device may be used as the substrate 100. The substrate 100 may be transparent or may not be transparent.

The first electrode 210 is formed on the substrate 100. A plurality of thin film transistors 120 may be formed on the substrate 100 before the first electrode 210 is formed. The thin film transistor 120 includes a gate electrode 121, a drain electrode 122, a source electrode 123, and a semiconductor layer 124 which are formed on the substrate 100. Further, a gate insulating layer 113 and an interlayer insulating layer 115 may be provided in the thin film transistor 120. However, a structure of the thin film transistor 120 is not limited to the form illustrated in FIG. 6 and may be configured in other forms. A buffer layer 111 formed, for example, of silicon oxide, silicon nitride, or the like may be further provided between the thin film transistor 120 and the substrate 100.

In the embodiment illustrated in FIG. 6, the first electrode 210 corresponds to an anode as a pixel electrode which is electrically connected to the thin film transistor 120, and the second electrode 230 corresponds to a cathode as a common electrode.

The first electrode 210 is electrically connected to the lower thin film transistor 120. In one embodiment, a planarization layer 117 covering the thin film transistor 120 is provided, and the first electrode 210 is disposed on the planarization layer 117. The first electrode 210 may be electrically connected to the thin film transistor 120 through a contact hole provided in the planarization layer 117.

The first electrode 210 may be formed as a transparent electrode or reflective electrode. When the first electrode 210 is formed as a transparent electrode, the first electrode 210 may be formed of ITO, IZO, ZnO, or In₂O₃, and when the first electrode 210 is formed as the reflective electrode, the first electrode 210 may include a reflective layer formed of Ag, Mg, Al, Pt, Pd, Au, Ni, Nd, Ir, Cr, or a compound thereof, and a layer formed of ITO, IZO, ZnO or In₂O₃ on the reflective layer. In the organic light emitting display device illustrated in FIG. 6, efficiency of top emission may be improved by forming the first electrode 210 as a reflective electrode.

In the organic light emitting display device illustrated in FIG. 6, the first electrode 210 serves as an anode and the second electrode 230 serves as a cathode, but, in another embodiment, the polarity of the first electrode 210 and the second electrode 230 may be reversed.

The pixel defining layer (PDL) 240 is provided between the first electrodes 210. The pixel defining layer 240 is formed of a material having an insulation property and separates the first electrodes 210 into pixel units. For example, the pixel defining layer 240 is disposed at each edge of the first electrodes 210 to separate the first electrodes 210 into pixel units, thereby defining pixel regions. The pixel defining layer 240, in one embodiment, covers the edge of the first electrode 210.

The emitting layer 220 is provided on the first electrode 210. The emitting layer 220 is formed in a pixel region which is an opening on the first electrode 210 separated by the pixel defining layer 240. The emitting layer 220 may include, for example, a red emitting layer 221, a green emitting layer 222, and a blue emitting layer 223.

Although not illustrated in FIG. 6, at least one of a hole injection layer and a hole transport layer may be further disposed on the first electrode 210.

The second electrode 230 is disposed on the emitting layer 220. The second electrode 230 may be formed to have a light transmission property in a top emission type organic light emitting display device. That is, the second electrode 230 may be formed as a transparent electrode. When the second electrode 230 is formed as a transparent electrode, it may include a layer formed of Li, Ca, LiF/Ca, LiF/AI, Al, Mg, or a compound thereof, and a layer formed thereon, which consists of a transparent electrode-forming material such as ITO, IZO, ZnO, In₂O₃, or the like. In a top emission type organic light emitting display device, as illustrated in FIG. 6, the second electrode 230 has a light transmission property, and the second electrode 230 may be formed, for example, by laminating a LiF/AI layer and an ITO layer.

Although not illustrated in FIG. 6, at least one of an electron injection layer and an electron transport layer may be further disposed between the emitting layer 220 and the second electrode 230.

In one embodiment, an auxiliary layer 250 may be disposed on the second electrode 230. The auxiliary layer 250 may facilitate fixing the slit-shaped pattern 300 on the second electrode 230. The auxiliary layer 250 may be formed by an adhesive transparent polymer resin or by metal thin film surface treatment. The auxiliary layer 250 may facilitate forming the slit-shaped pattern 300 by a transfer method.

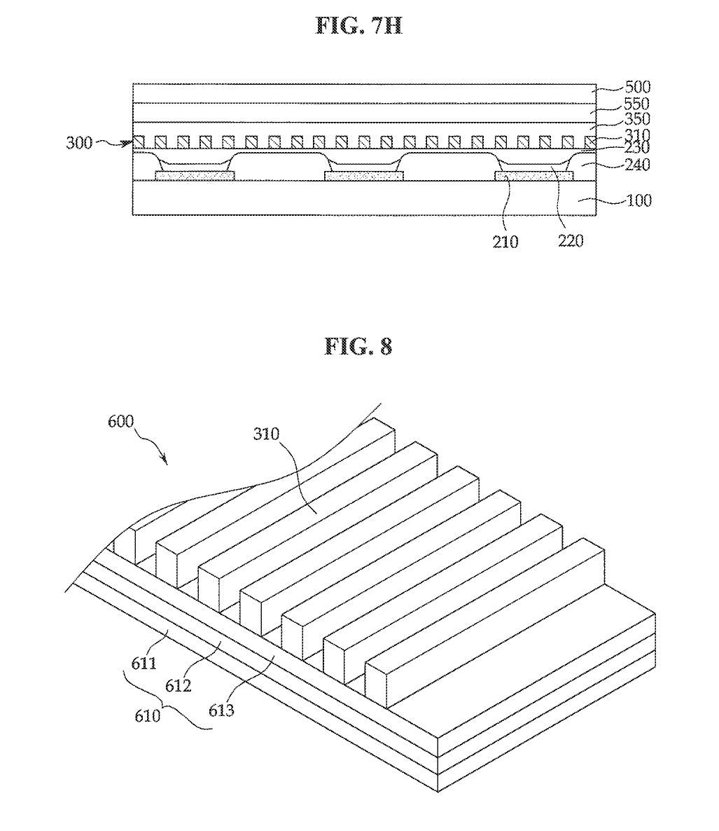

The slit-shaped pattern 300, in one embodiment, is formed on the auxiliary layer 250. The slit-shaped pattern 300 may be formed by a transfer method. For example, a transfer sheet 600 (see FIG. 7E) having the plurality of protrusions 310 for forming the slit-shaped pattern 300 may be used, and the plurality of protrusions 310 disposed on the transfer sheet 600 is transferred on the auxiliary layer 250, thereby forming the slit-shaped pattern 300. A shape and structure of the slit-shaped pattern 300 are described above.

A planarization layer 350 may be disposed on the slit-shaped pattern 300 having the plurality of protrusions 310 spaced apart from each other so as to planarize an upper side of the slit-shaped pattern 300. The planarization layer 350 may be a passivation layer.

A window 500 is disposed above the planarization layer 350. Further, a touch panel 700 for touch input may be disposed between the window 500 and the planarization layer 350, and an adhesive layer 710 may be used to bond the touch panel 700 to the window 500.

According to an embodiment of the present invention, a manufacturing method of an organic light emitting display device is provided.

A manufacturing method of the organic light emitting display device according to an embodiment of the present invention includes forming the first electrode 210 on the substrate 100, forming the emitting layer 220 on the first electrode 210, forming the second electrode 230 on the emitting layer 220, and forming the slit-shaped pattern 300 including the plurality of protrusions 310 spaced apart from each other on the second electrode 230.

A manufacturing method of an organic light emitting display device according to an embodiment of the present invention is described below with reference to FIGS. 7A to 7H.

As illustrated in FIG. 7A, the first electrode 210 is formed on the substrate 100. The substrate 100 and the first electrode 210 are described above. The first electrode 210 is patterned to form a pixel unit.

As illustrated in FIG. 7B, the pixel defining layer 240 separating the first electrode 210 into pixel units is formed.

Although not illustrated in FIGS. 7A to 7H, the slit-shaped pattern 400 may be formed on the first electrode 210 after the first electrode 210 is formed. A method of forming the slit-shaped pattern 400 on the first electrode 210 may be the same as that of forming the slit-shaped pattern 300 on the second electrode 230, which will be described below.

The emitting layer 220 is formed on an opening of the first electrode 210 separated by the pixel defining layer 240 (see FIG. 7C).

The second electrode 230 is formed over (e.g., completely covering) a surface of the pixel defining layer 240 and the emitting layer 220 (see FIG. 7D).

The slit-shaped pattern 300 having the plurality of protrusions 310 is formed on the second electrode 230. In the forming of the slit-shaped pattern 300, the protrusions 310 may be formed by using at least one of a metal or a metal oxide. The structures of the slit-shaped pattern 300 and the protrusions 310 are described above.

In the forming of the slit-shaped pattern 300, a transfer method using a transfer sheet may be applied thereto. That is, the forming of the slit-shaped pattern 300 may include preparing the transfer sheet 600 having the plurality of protrusions 310 and transferring the plurality of protrusions 310 included in the transfer sheet 600 to the second electrode 230.

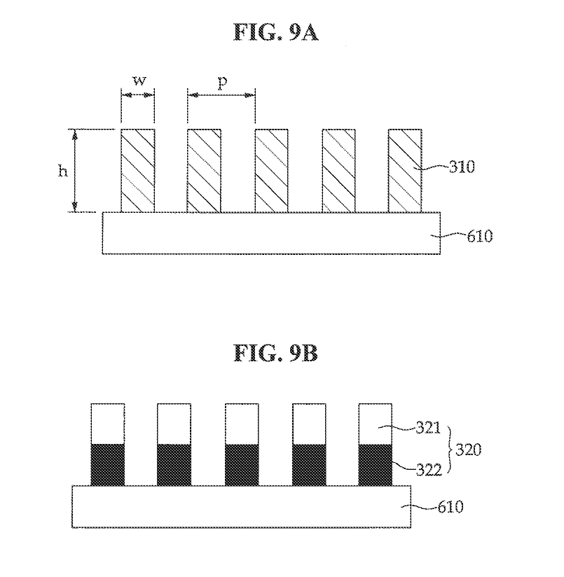

In order to form the slit-shaped pattern 300 by using the transfer method, the transfer sheet 600 including the plurality of protrusions 310 is prepared. The transfer sheet 600 may include a base part 611, a light to heat conversion layer 612 formed on the base part 611, an expansion layer 613 formed on the light to heat conversion layer 612, and the plurality of protrusions 310 formed on the expansion layer 613. Here, the base part 611, the light to heat conversion layer 612, and the expansion layer 613 are referred to as a base sheet 610. An example of the transfer sheet 600, according to one embodiment, is illustrated in FIG. 8.

In order to form the slit-shaped pattern 300 by a transfer method, as shown in FIG. 7E, the transfer sheet 600 is disposed above the second electrode 230.

Next, light is irradiated on the transfer sheet 600. The irradiated light is converted into heat in the light to heat conversion layer 612 and expands the expansion layer 613. As a result, the protrusions 310 on the expansion layer 613 are transferred to the second electrode 230. In one embodiment, a laser may be used as a light source of the irradiated light.

In one embodiment, a separate auxiliary layer may be further disposed such that the protrusions 310 may be easily attached to the second electrode 230, such as the auxiliary layer 250 described above with reference to FIG. 6. In one embodiment, the protrusions 310 may be easily attached to the second electrode 230 by surface treatment of the second electrode 230. In one embodiment, after the transfer, the protrusions 310 may be stably fixed on the second electrode 230 by heat treatment.

After the transfer, the slit-shaped pattern 300 is formed on the second electrode 230 as illustrated in FIG. 7F.

The planarization layer 350 is disposed on the slit-shaped pattern 300 (see FIG. 7G), and then the window 500 is disposed above the planarization layer 350 (see FIG. 7H). In one embodiment, a separation space 550 may be provided between the planarization layer 350 and the window 500. In one embodiment, a touch panel, such as the touch panel 700 described above with reference to FIG. 6, may be disposed on a lower part of the window 500.

FIG. 8 illustrates the transfer sheet 600, according to an embodiment of the present invention, which is applicable to the transfer method. The transfer sheet 600 includes the base part 611, the light to heat conversion layer 612 formed on the base part 611, the expansion layer 613 formed on the light to heat conversion layer 612, and the plurality of protrusions 310 formed on the expansion layer 613. Here, the base part 611, the light to heat conversion layer 612 and the expansion layer 613 are referred to as the base sheet 610.

The shape, width “w,” and height “h” of the protrusions 310 formed on the second electrode 230, and the distance “p” between adjacent ones of the protrusions 310 may be adjusted by adjusting the shape, width “w,” and height “h” of the plurality of protrusions 310 formed on the base sheet 610 of the transfer sheet 600, and the distance “p” between the protrusions 310.

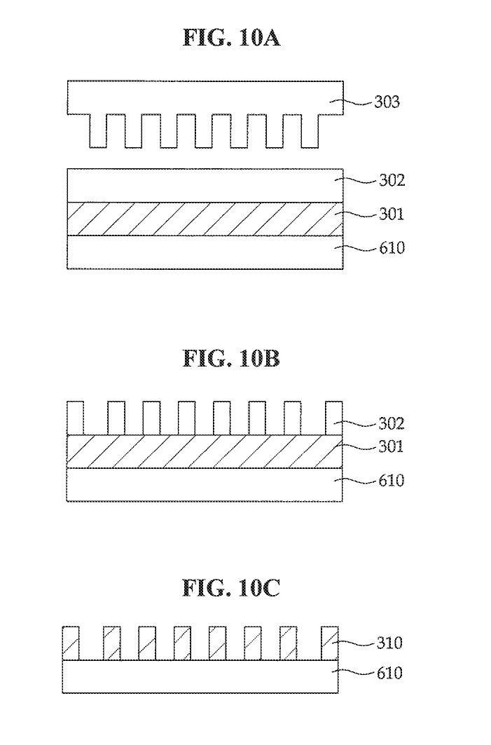

FIGS. 9A and 9B illustrate examples of a shape of the protrusions 310 and 320 disposed on the base sheet 610 of the transfer sheet 600, respectively. The protrusions 310 may be formed by using a metal or a metal oxide. A shape of the protrusions 320 disposed on the base sheet 610, as illustrated in FIG. 9B, may have a structure including the black matrix layer 322 formed of a metal oxide and the metal layer 321 disposed on the black matrix layer 322.

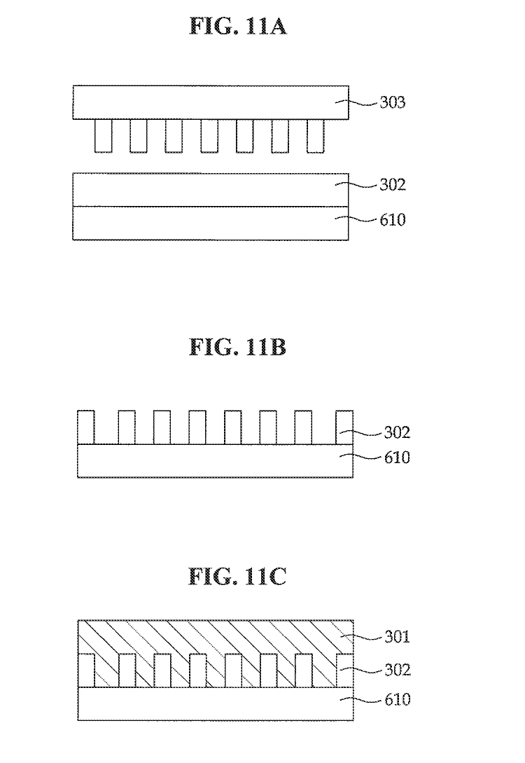

FIGS. 10A to 10C illustrate a process of forming the plurality of protrusions 310 on the base sheet 610 of the transfer sheet 600, according to an embodiment of the present invention. Forming the plurality of protrusions 310 on the base sheet 610 may include forming a metal thin layer 301 on the base sheet 610 and forming a protrusion formed of metal by imprinting the metal thin layer 301.

In one embodiment, as illustrated in FIG. 10A, the metal thin layer 301 is formed on the base sheet 610, and a photoresist 302 is disposed on the metal thin layer 301. Then, a pattern is formed in the photoresist 302 by using an imprinter 303 having a pattern. As a result, a pattern, as illustrated in FIG. 10B, is formed in the photoresist 302.

As illustrated in FIG. 10C, the plurality of protrusions 310 spaced apart from each other may be formed by selectively etching the metal thin layer 301 by using the pattern in the photoresist 302.

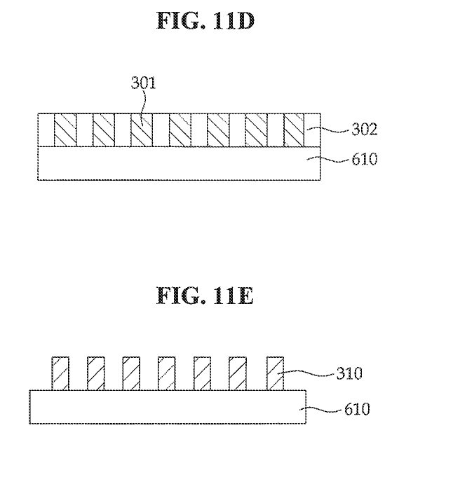

FIGS. 11A to 11E illustrate a process of forming the plurality of protrusions 310 on the base sheet 610 of the transfer sheet 600, according to another embodiment of the present invention.

In one embodiment, as illustrated in FIG. 11A, the photoresist 302 is disposed on the base sheet 610, and a pattern is formed in the photoresist 302 by using the imprinter 303 having a pattern. As a result, a pattern, as illustrated in FIG. 11B, is formed in the photoresist 302.

Then, the metal thin layer 301 is formed by filling the pattern formed of the photoresist 302 with a metal (see FIG. 11C). The metal thin layer 301 is removed down to a height of the photoresist 302 pattern (see FIG. 11D), such as by chemical mechanical polishing (CMP). Then, the photoresist 302 is stripped so that only the protrusions 310 formed of a metal remain (see FIG. 11E).

From the foregoing disclosure, it will be appreciated that various embodiments of the present invention have been described herein for purposes of illustration, and that various modifications may be made without departing from the spirit and scope of the present invention. Accordingly, the various embodiments described herein are not intended to be limiting, with the true spirit and scope being indicated by the following claims and equivalents thereof.

What is claimed is:

1. An organic light emitting display device, comprising:
a substrate;
a first electrode on the substrate;
an emitting layer on the first electrode;
a second electrode on the emitting layer; and
a first slit-shaped pattern on the second electrode and including a plurality of first protrusions spaced apart from each other.

2. The organic light emitting display device of claim 1, wherein the second electrode transmits light.

3. The organic light emitting display device of claim 1, further comprising a second slit-shaped pattern on the first electrode and including a plurality of second protrusions spaced apart from each other.

4. The organic light emitting display device of claim 3, wherein the second slit-shaped pattern on the first electrode has a same structure as the first slit-shaped pattern on the second electrode.

5. The organic light emitting display device of claim 1, wherein a cross section of a protrusion of the plurality of first protrusions has a quadrangular shape or a U-shape.

6. The organic light emitting display device of claim 1, wherein a protrusion of the plurality of first protrusions has a height of about 100 nm to about 200 nm and a width of about 30 nm to about 100 nm.

7. The organic light emitting display device of claim 1, wherein a distance between adjacent protrusions of the plurality of first protrusions is about 60 nm to about 250 nm.

8. The organic light emitting display device of claim 1, wherein the first protrusions comprise at least one of a metal or a metal oxide.

9. The organic light emitting display device of claim 8, wherein the metal comprises at least one selected from the group consisting of aluminum (Al), chromium (Cr), and silver (Ag).

10. The organic light emitting display device of claim 1, wherein the first protrusions comprise a metal layer.

11. The organic light emitting display device of claim 10, further comprising a black matrix layer on the metal layer.

12. The organic light emitting display device of claim 11, wherein the black matrix layer covers a surface of the metal layer.

13. The organic light emitting display device of claim 11, wherein the black matrix layer comprises a metal oxide.

14. The organic light emitting display device of claim 13, wherein the metal oxide comprises at least one selected from the group consisting of aluminum oxide, chromium oxide, and silver oxide.

15. A manufacturing method of an organic light emitting display device, the method comprising:
forming a first electrode on a substrate;
forming an emitting layer on the first electrode;
forming a second electrode on the emitting layer; and
forming a first slit-shaped pattern on the second electrode, the first slit-shaped pattern including a plurality of first protrusions spaced apart from each other.

16. The manufacturing method of an organic light emitting display device of claim 15, wherein in the forming of the first slit-shaped pattern, at least one of a metal or a metal oxide is used to form the first protrusions.

17. The manufacturing method of an organic light emitting display device of claim 15, wherein the forming of the first slit-shaped pattern comprises:
preparing a transfer sheet having the plurality of first protrusions thereon; and
transferring the plurality of first protrusions from the transfer sheet to the second electrode.

18. The manufacturing method of an organic light emitting display device of claim 15, further comprising:
forming a second slit-shaped pattern on the first electrode after the forming the first electrode and before the forming the emitting layer, the second slit-shaped pattern including a plurality of second protrusions spaced apart from each other.

19. The manufacturing method of an organic light emitting display device of claim 18, wherein the forming the second slit-shaped pattern on the first electrode is performed in a same manner as the forming the first slit-shaped pattern on the second electrode.
